(19) United States
(12) Patent Application Publication
(10) Pub. No.: US 2026/0237086 A1
(43) Pub. Date: Aug. 13, 2026

(54) MASK SHAPE CALCULATION METHOD, PROGRAM, AND STORAGE MEDIUM

(71) Applicant: Kioxia Corporation, Tokyo (JP)

(72) Inventors: Taiki KIMURA, Minato Tokyo (JP); Masafumi SUZUKI, Chigasaki Kanagawa (JP)

(21) Appl. No.: 19/324,290

(22) Filed: Sep. 10, 2025

(30) Foreign Application Priority Data
Feb. 10, 2025 (JP) 2025-020172

(51) Int. Cl. G06T 7/564; G03F 1/70; G06T 7/13

(52) U.S. Cl. CPC G06T 7/564; G03F 1/70; G06T 7/13; G06T 2207/20048; G06T 2207/30148

(57) ABSTRACT

A method includes sampling K points based on a lithography target; selecting a first kernel provided in a first function representing a projection optical system related to a mask shape corresponding to the lithography target; determining a first optical image intensity at each of the K points corresponding to a first convolution integral of the first kernel and a second function representing the mask shape; discretizing the first convolution integral into N dimensions to generate a first matrix of K rows and N columns related to the first kernel and a first vector of K rows related to the first optical image intensity; and solving a linear equation Am=b using a matrix A including the first matrix, a vector b including the first vector, and a vector m corresponding to the second function, and calculating the second function.

### CROSS-REFERENCE TO RELATED APPLICATION

This application is based upon and claims the benefit of priority from Japanese Patent Application No. 2025-020172, filed Feb. 10, 2025, the entire contents of which are incorporated herein by reference.

### FIELD

Embodiments described herein relate generally to a mask shape calculation method, a program, and a storage medium.

### BACKGROUND

As a memory device is miniaturized, a method of calculating a complex mask shape at high speed and with high accuracy in order to allocate a lithography margin is being studied. For example, an inverse lithography technology (ILT) is known as a technology for obtaining a mask shape for obtaining a desired resist shape on a wafer.

### DESCRIPTION OF THE DRAWINGS

FIG. 1 is a block diagram illustrating an example of a configuration of a mask manufacturing system according to a first embodiment.

FIG. 2 is a block diagram illustrating an example of a hardware configuration of a mask data generation device according to the first embodiment.

FIG. 3 is a block diagram illustrating an example of a functional configuration of the mask data generation device according to the first embodiment.

FIG. 4 is a diagram illustrating a first example of an eigenfunction of a Socs kernel that is input to an initial value generation module according to the first embodiment.

FIG. 5 is a diagram illustrating a second example of an eigenfunction of the socs kernel that is input to the initial value generation module according to the first embodiment.

FIG. 6 is a diagram illustrating a third example of the eigenfunction of the socs kernel that is input to the initial value generation module according to the first embodiment.

FIG. 7 is a diagram illustrating an example of an eigenvalue of the Socs kernel that is input to the initial value generation module according to the first embodiment.

FIG. 8 is a block diagram illustrating an example of a functional configuration of the initial value generation module according to the first embodiment.

FIG. 9 is a diagram illustrating an example of a relationship between design data and representative points input to the initial value generation module according to the first embodiment.

FIG. 10 is a diagram illustrating an example of a relationship between initial value data that is output from the initial value generation module according to the first embodiment and design data.

FIG. 11 is a flowchart illustrating an example of initial value generation processing in the initial value generation module according to the first embodiment.

FIG. 12 is a flowchart illustrating an example of generation processing in the initial value vector generation module according to the first embodiment.

FIG. 13 is a flowchart illustrating an example of matrix generation processing in the initial value generation module according to the first embodiment.

FIG. 14 is a diagram illustrating an example of a condition considered by the initial value generation module according to a second embodiment.

FIG. 15 is a flowchart illustrating an example of initial value generation processing in the initial value generation module according to the second embodiment.

FIG. 16 is a flowchart illustrating an example of vector generation processing in the initial value generation module according to the second embodiment.

FIG. 17 is a flowchart illustrating an example of matrix generation processing in the initial value generation module according to the second embodiment.

FIG. 18 is a flowchart illustrating an example of initial value generation processing in the initial value generation module according to a modification example.

### DETAILED DESCRIPTION

A mask shape is calculated at high speed.

In general, according to one embodiment, a mask shape calculation method includes sampling K representative points from a contour of a lithography target, wherein K is an integer equal to or greater than 1; selecting a first kernel provided in a first function representing a projection optical system related to a mask shape corresponding to the lithography target; determining a first optical image intensity at each of the K representative points corresponding to a first convolution integral of the first kernel and a second function representing the mask shape; discretizing the first convolution integral into N dimensions to generate (i) a first matrix of K rows and N columns related to the first kernel; and (ii) a first vector of K rows related to the first optical image intensity; and solving a linear equation Am=b using a matrix A including the first matrix, a vector b including the first vector, and a vector m corresponding to the second function, and calculating the second function.

Next, embodiments will be described with reference to the drawings. In the following description, elements having the same function and configuration are designated by a common reference numeral.

### 1. FIRST EMBODIMENT

### 1.1 Configuration

### 1.1.1 Mask Manufacturing System

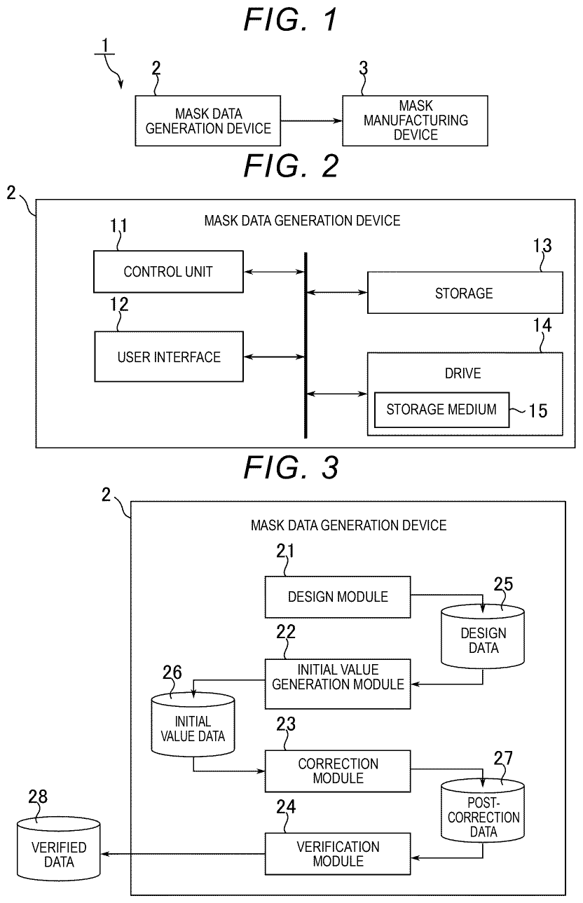

FIG. 1 is a block diagram illustrating an example of a hardware configuration of a mask manufacturing system according to an embodiment. A mask manufacturing system 1 is a system for manufacturing a photomask (hereinafter, simply referred to as a “mask”). The mask manufacturing system 1 includes a mask data generation device 2 and a mask manufacturing device 3.

The mask data generation device 2 is a computer configured to calculate a mask shape. The mask data generation device 2 generates mask data as a calculation result of a mask shape.

The mask manufacturing device 3 is an electron beam drawing device. The mask manufacturing device 3 draws a pattern based on the mask data generated by the mask data generation device 2 by irradiating a substrate, which is a material of a photomask, with an electron beam. Thereafter, the substrate on which the pattern is drawn is processed into a mask by development processing and etching processing.

The mask is used, for example, in manufacturing a memory device. The memory device is, for example, a NAND flash memory including a three-dimensional memory cell array.

### 1.1.2 Mask Data Generation Device

FIG. 2 is a block diagram illustrating an example of a hardware configuration of the mask data generation device according to the first embodiment. The mask data generation device 2 includes a control unit 11, a user interface 12, a storage 13, a drive 14, and a storage medium 15.

The control unit 11 is a circuit that controls each element of the mask data generation device 2 as a whole. The control unit 11 includes a central processing unit (CPU), a random access memory (RAM), a read only memory (ROM), and the like. The ROM of the control unit 11 stores a program or the like used in various processing in the mask data generation device 2. The CPU of the control unit 11 controls the entire mask data generation device 2 in accordance with a program stored in the ROM of the control unit 11. The RAM of the control unit 11 is used as a work area of the CPU of the control unit 11.

The user interface 12 is an interface that governs communication between a user and the control unit 11. The user interface 12 includes an input device and an output device. The input device includes, for example, a touch panel, an operation button, and the like. The output device includes, for example, a liquid crystal display (LCD) or an electroluminescence (EL) display.

The user interface 12 converts an input from the user into an electrical signal and then transmits the electrical signal to the control unit 11. The user interface 12 outputs an execution result of various processing based on the input from the user, to the user.

The storage 13 includes, for example, a hard disk drive (HDD) or a solid state drive (SSD). The storage 13 stores data used in various processing in the mask data generation device 2.

The drive 14 is a device for reading software stored in the storage medium 15. The drive 14 includes, for example, a compact disk (CD) drive, a digital versatile disk (DVD) drive, and the like.

The storage medium 15 is a medium that stores the software by electrical, magnetic, optical, mechanical, or chemical action. The storage medium 15 may store a program for executing various processing in the mask data generation device 2.

FIG. 3 is a block diagram illustrating an example of a functional configuration of the mask data generation device according to the first embodiment. The CPU of the control unit 11 deploys a program stored in the ROM of the control unit 11 or the storage medium 15 to the RAM of the control unit 11. The CPU of the control unit 11 interprets and executes the program deployed in the RAM of the control unit 11. Thereby, the mask data generation device 2 functions as a computer including a design module 21, an initial value generation module 22, a correction module 23, and a verification module 24.

The design module 21 is a functional block for generating a design data 25. The design data 25 is data representing a layout of an ideal pattern expected to be transferred to the substrate using the mask. That is, the design data 25 is data representing a shape (a lithography target) to be a target of a resist after lithography. The design module 21 transmits the generated design data 25 to the initial value generation module 22.

The initial value generation module 22 is a functional block for generating an initial value (initial value data 26) of the mask data based on the design data 25. The initial value generation module 22 linearizes a nonlinear equation showing a relationship between an optical system (projection optical system) of a projection exposure device and a mask shape, and an optical image intensity (complex amplitude of an optical image) by giving a predetermined restriction. The initial value generation module 22 calculates an approximate mask shape by solving the linearized equation.

Such a solution is also called a pseudo inverse lithography technology (quasi-ILT) with respect to an inverse lithography technology (ILT) that calculates an exact solution of the mask shape by solving the nonlinear equation. The initial value generation module 22 transmits the generated initial value data 26 to the correction module. Details of generation processing of the initial value data 26 in the initial value generation module 22 will be described below.

The correction module 23 is a functional block for correcting the initial value data 26. Specifically, the correction module 23 executes optical proximity correction (OPC) processing on the initial value data 26 generated by the initial value generation module 22. The correction module 23 transmits the corrected mask data (post-correction data 27) to the verification module 24.

The verification module 24 is a functional block for verifying the post-correction data 27 generated by the correction module 23. Specifically, the verification module 24 executes a lithography simulation on the post-correction data. The verification module 24 determines whether a desired pattern is obtained by lithography processing using the mask based on the post-correction data 27 by the lithography simulation. In a case where it is determined that the desired pattern is not obtained (verification NG), the verification module 24 performs correction processing on the post-correction mask data, and executes the lithography simulation again. In a case where it is determined that the desired pattern is obtained (verification OK), the verification module 24 tapes out the post-correction mask data to the mask manufacturing device 3 as final mask data (verified data 28).

### 1.1.3 Initial Value Generation Module

### 1.1.3.1 Pseudo Inverse Lithography Technology

First, an outline of the pseudo inverse lithography technology executed by the initial value generation module according to the first embodiment will be described.

An optical image obtained by transferring the mask shape to a wafer via the projection optical system can be obtained using a function called a transmission cross coefficient (TCC). The TCC is a function that can be uniquely determined when a condition of the projection optical system is determined. When the TCC is deployed into a sum of coherent systems (SOCS) using the eigenfunction, where the eigenfunction of a p-th Socs kernel is Sₚ(x, y) and the eigenvalue is op, an optical image intensity I(x, y) of the mask shape formed on the wafer is represented by Equation (1) below.

$$I ( x , y ) = {\sum }_{p = 1}^{} {σ}_{p} {\vert ( {S}_{p} ⊗ M ) ( x , y ) \vert}^{2} \qquad ( 1 )$$

Here, the mask function M(x, y) is a function representing the mask shape. Specifically, for example, the mask function M(x, y) has different values in an outside and an inside of the mask shape, and is defined on an xy plane so that, for example, the outside is 0 and the inside is 1. p is an integer of 1 or more. As described above, the optical image intensity I is calculated based on the square of the convolution integral of the eigenfunction Sₚ and the mask function M.

The pattern shape formed on the wafer is given by a contour line in which the optical image intensity I is a desired constant. In the inverse lithography technology, a mask function M is obtained such that the optical image intensity I is a desired constant by solving an inverse problem of Equation (1). On the other hand, in the pseudo inverse lithography technology according to the present embodiment, a restriction is given that the value of each term of the convolution integral in Equation (1) is a desired constant along the pattern shape.

When the eigenfunction Sₚ of the p-th SOCS kernel is degenerated, the above restriction is not satisfied only by the value of the convolution integral of the eigenfunction Sₚ and the mask function M.

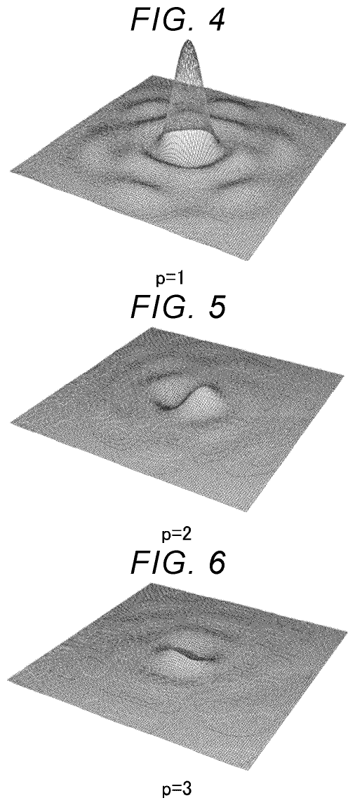

FIG. 4 is a diagram illustrating a first example of the eigenfunction of the socs kernel that is input to the initial value generation module according to the first embodiment. FIG. 5 is a diagram illustrating a second example of an eigenfunction of the Socs kernel that is input to the initial value generation module according to the first embodiment. FIG. 6 is a diagram illustrating a third example of the eigenfunction of the SOCs kernel that is input to the initial value generation module according to the first embodiment. Each of FIGS. 4, 5, and 6 illustrates an xy distribution of a real part when a phase of a center of the eigenfunction of the Socs kernel is set to zero. FIGS. 4, 5, and 6 correspond to a kernel eigenfunction S₁ of a first Socs, a kernel eigenfunction S₂ of a second socs, and a kernel eigenfunction S₃ of a third SOCS, respectively.

As illustrated in FIG. 4, since the first socs kernel is not degenerated, it is expected that the value of the convolution integral of the eigenfunction S₁ and the mask function M is a desired constant along the pattern shape. In contrast, as illustrated in FIGS. 5 and 6, since the second Socs kernel and the third Socs kernel are degenerated, it is not expected that the value of the convolution integral of each of the eigenfunctions S₂ and S₃, and the mask function M along the pattern shape is the desired constant. However, the eigenfunctions S₂ and S₃ have symmetry with each other. In such a case, it is expected that a sum of the value of the convolution integral of the eigenfunction S₂ and the mask function M and the value of the convolution integral of the eigenfunction S₃ and the mask function M is the desired constant along the pattern shape. Hereinafter, for convenience of explanation, a set of the non-degenerated SOCs kernels or the degenerated SOCS kernels is referred to as a Socs kernel group.

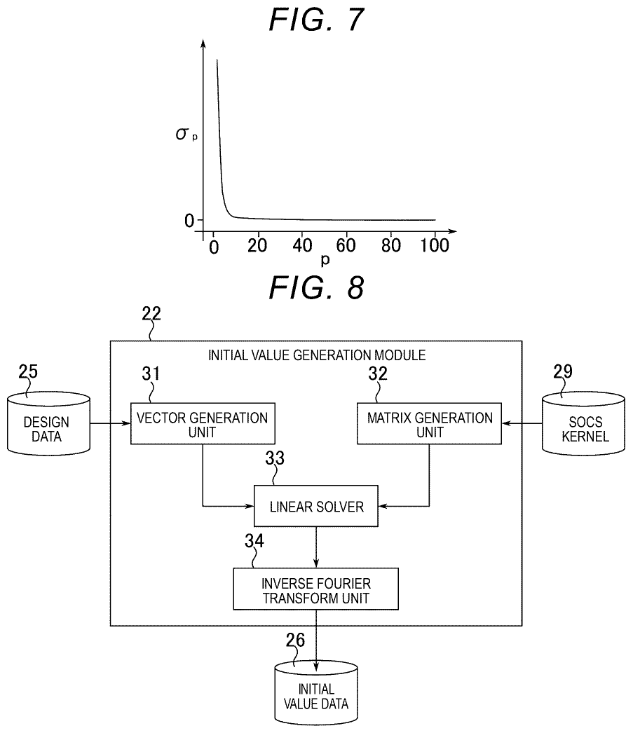

FIG. 7 is a diagram illustrating an example of an eigenvalue of the socs kernel that is input to the initial value generation module according to the first embodiment. As illustrated in FIG. 7, the eigenvalue Op is rapidly decreased as the value p increases. Therefore, the contribution degree of each term in Equation (1) is rapidly decreased as the value p increases. Therefore, in Equation (2), the term to be considered as a calculation target may be sufficient up to p=3. In this case, the number z of the socs kernel groups to be considered as the calculation target is two, which are the kernel group including the first Socs kernel and the kernel group including the second and third SOCS kernels.

Hereinafter, a case where the socs kernel group up to z=2 is considered as the calculation target will be described. In this case, in the pseudo inverse lithography technology according to the present embodiment, Equations (2-1) and (2-2) are solved.

$${I}_{1} ( x , y ) = ( {S}_{1} ⊗ M ) ( x , y ) = {b}_{1} \qquad ( 2 - 1 )$$

$${I}_{2} ( x , y ) + {I}_{3} ( x , y ) = ( {S}_{2} ⊗ M ) ( x , y ) + ( {S}_{3} ⊗ M ) ( x , y ) = {b}_{2} \qquad ( 2 - 2 )$$

Next, it will be described that Equations (2-1) and (2-2) are linear equations. Hereinafter, for convenience of explanation, the Equation (2-1) is assumed in which the SOCS kernel is not degenerated unless otherwise specified.

Equation (2-1) is represented as Equation (3) below when expressed as an integral.

$${I}_{1} ( x , y ) = {\int }_{- ∞}^{∞} {\int }_{- ∞}^{∞} {S}_{1} ( x - u , y - v ) M ( u , v ) dudv \qquad ( 3 )$$

Equation (3) is represented as Equation (4) below using the property of the Fourier transform of the convolution integral. The function after the Fourier transform is represented by adding a tilde to the function name.

$$\text{?} ( ξ , η ) = \text{?} ( ξ , η ) \cdot \tilde{M} ( ξ , η ) \qquad ( 4 )$$

Further, when Equation (4) is subjected to inverse Fourier transform, Equation (4) is represented by Equation (5) below.

$${I}_{1} ( x , y ) = {\int }_{- ∞}^{∞} {\int }_{- ∞}^{∞} \tilde{{S}_{1}} ( ξ , η ) \cdot \tilde{M} ( ξ , η ) {e}^{i ξ x + i η y} d ξ d η \qquad ( 5 )$$

Equation (5) is satisfied at a representative points of K (1≤k≤K) on the contour of the lithography target in the design data 25. Here, K is an integer of 1 or more. That is, as shown in Equation (2-1), when the optical image intensity I₁(xₖ, yₖ) at the k-th point (xₖ, yₖ) on the contour is all the value b₁, Equation (6) shown below is obtained by introducing this into Equation (5).

$${I}_{1} ( {x}_{k} , {y}_{k} ) = {\int }_{- ∞}^{∞} {\int }_{- ∞}^{∞} \tilde{{S}_{1}} ( ξ , η ) \cdot \tilde{M} ( ξ , η ) {e}^{i ξ {x}_{k} + i η {y}_{k}} d ξ d η = {b}_{1} \qquad ( 6 )$$

Next, Equation (6) is discretized. The integral in Equation (6) is with respect to a wave number space (ξ, n), and is discretized as (ξ_{c}, n_{d}) using variables c and d. The variable c is an integer −C or more and C or less. The variable d is an integer −D or more and D or less. The values C and D are integers of 1 or more representing an integration interval. N=(2C+1) (2D+1) that is a product of the number of integration intervals is also referred to as a dimension or the number of sample points of the Fourier transform. A dimension N of the Fourier transform is an integer of (2+1) (2+1)=9 or more. By discretizing and calculating in a Fourier space, it is possible to prevent the resolution in a real space from being restricted by the dimension N of discretization.

In discretization, a variable j shown in Equation (7) below is introduced, and a double sum of the variables c and d is expressed as a single sum of the variable j.

$$j = ( 2 D + 1 ) c + d \qquad ( 7 )$$

Then, the replacement is performed as in Equation (8-1).

$$\{ \begin{matrix}{\tilde{a}}_{1 \_ kj} = \text{?} ( {ξ}_{c} , {η}_{d} ) {e}^{{iξ}_{c} {x}_{k} + i {η}_{d} {y}_{k}} ΔξΔη \\ {\tilde{m}}_{j} = \tilde{M} ( {ξ}_{c} , {η}_{d} )\end{matrix} \qquad ( 8 - 1 )$$

Thereby, Equation (2-1) is Equation (9-1) shown below.

$${I}_{1} ( {x}_{k} , {y}_{k} ) = {\sum }_{j} {\tilde{a}}_{1 \_ kj} {\tilde{m}}_{j} = {b}_{1} \qquad ( 9 - 1 )$$

In the case of Equation (2-2), the replacement is performed as in Equation (8-2).

$${\tilde{a}}_{2 \_ kj} = ( \text{?} ( {ξ}_{c} , {η}_{d} ) + \text{?} ( {ξ}_{c} , {η}_{d} ) ) {e}^{{iξ}_{c} {x}_{k} + i {η}_{d} {y}_{k}} ΔξΔη \qquad ( 8 - 2 )$$

Thereby, Equation is Equation (9-2) shown below.

$${I}_{2} ( {x}_{k} , {y}_{k} ) + {I}_{3} ( {x}_{k} , {y}_{k} ) = {\sum }_{j} {\tilde{a}}_{2 \_ k j} {\tilde{m}}_{j} = {b}_{2} \qquad ( 9 - 2 )$$

Equations (9-1) and (9-2) are established for each of the K representative points on the lithography target. Based on such Equations (9-1) and (9-2), a matrix and a vector shown in Equation (10) below are defined.

$$\{ \begin{matrix}A = ( \begin{matrix}{\tilde{a}}_{1 \_ 11} & … & {\tilde{a}}_{1 \_ 1 N} \\ ⋮ & ⋱ & ⋮ \\ {\tilde{a}}_{1 \_ K 1} & … & {\tilde{a}}_{1 \_ KN} \\ {\tilde{a}}_{2 \_ 11} & … & {\tilde{a}}_{2 \_ 1 N} \\ ⋮ & ⋱ & ⋮ \\ {\tilde{a}}_{2 \_ K 1} & … & {\tilde{a}}_{2 \_ KN}\end{matrix} ) \\ m = ( \begin{matrix}{\tilde{m}}_{1} & … & {{\tilde{m}}_{N} )}^{T}\end{matrix} \\ b = ( \begin{matrix}{b}_{1} & … & {b}_{1} & {b}_{2} & … & {{b}_{2} )}^{T}\end{matrix}\end{matrix} \qquad ( 10 )$$

Thereby, Equations (2-1) and (2-2) can be regarded as linear equations shown in Equation (11) below.

$$Am = b \qquad ( 11 )$$

The vector m corresponding to the Fourier transform of the mask function M can be obtained by solving Equation (11). The mask function M is calculated by performing inverse Fourier transform on the obtained vector m.

### 1.1.3.2 Functional Configuration

FIG. 8 is a block diagram illustrating an example of a functional configuration of the initial value generation module according to the first embodiment. The initial value generation module 22 includes a vector generation unit 31, a matrix generation unit 32, a linear solver 33, and an inverse Fourier transform unit 34.

The vector generation unit 31 samples K representative points from the contour of the lithography target shown in the design data 25. The vector generation unit 31 determines a common value for the K sampled representative points. More specifically, the vector generation unit 31 determines the value b₁ corresponding to p=1 and the value b₂ corresponding to the set of p=2 and 3 for K representative points. A size relationship between the values b₁ and b₂ corresponds to a size relationship between the eigenvalues σ₁ and σ₂. That is, the value of b₁ is determined to be significantly larger than the value of b₂. The vector generation unit 31 generates the vector b of 2K rows in Equation (11) based on the determined values b₁ and b₂. The vector generation unit 31 transmits the generated vector b to the linear solver 33.

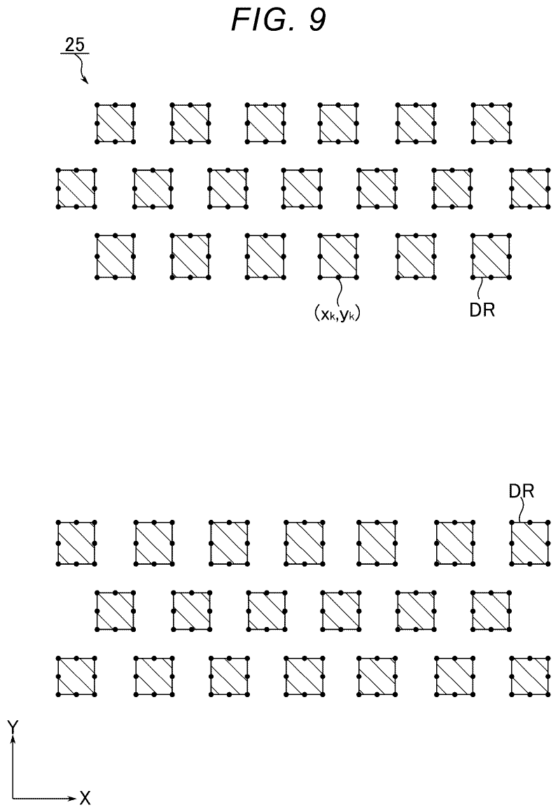

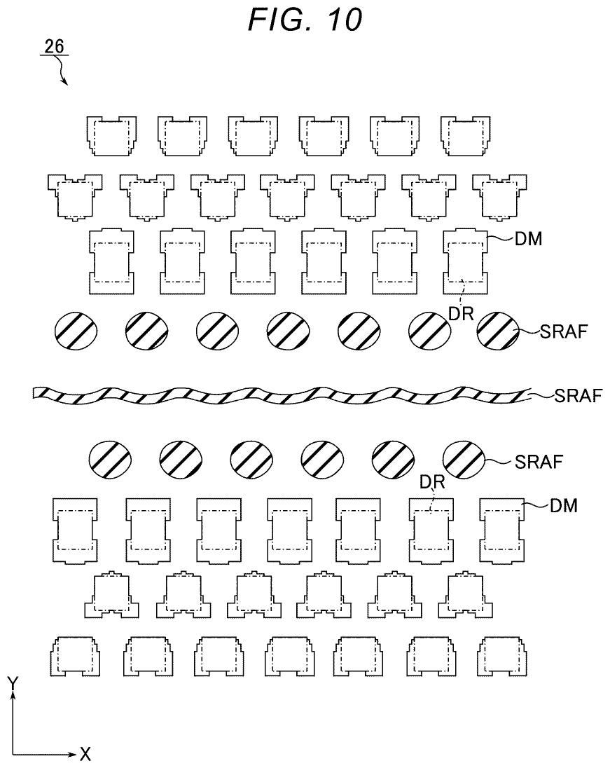

FIG. 9 is a diagram illustrating an example of a relationship between design data and representative points input to the initial value generation module according to the first embodiment. In FIG. 9, a lithography target DR shown in the design data 25 is indicated by hatching.

As illustrated in FIG. 9, the representative points (xₖ, yₖ) are sampled at characteristic portions (for example, vertices or midpoints of edges) of the shape representing the lithography target DR. The example of FIG. 9 illustrates a case where a total of eight points including vertices and midpoints of the edges are sampled for one rectangular lithography target DR.

The matrix generation unit 32 performs the Fourier transform on the eigenfunction Sₚ of the SOCS kernel 29 to generate the matrix A in Equation (11). The matrix generation unit 32 transmits the generated matrix A to the linear solver 33.

When receiving the vector b and the matrix A from the vector generation unit 31 and the matrix generation unit 32, respectively, the linear solver 33 calculates the vector m corresponding to the Fourier transform of the mask function M by solving Equation (11). Equation (11) is an underdetermined problem because the number of columns N is larger than the number of rows 2K (2K<N). In addition, since a maximum singular value of the coefficient matrix in Equation (11) is very large with respect to a minimum singular value, it is difficult to uniquely solve Equation (11). Therefore, the linear solver 33 solves Equation (11) as a least square problem. Specifically, for example, the linear solver 33 solves Equation (11) using a least square minimum-residual method (LSMR method). The linear solver 33 transmits the calculated vector m to the inverse Fourier transform unit 34.

The inverse Fourier transform unit 34 executes the inverse Fourier transform on the vector m calculated by the linear solver 33 to calculate the mask function M. The inverse Fourier transform unit 34 transmits the calculated mask function M to the correction module 23 as the initial value data 26.

FIG. 10 is a diagram illustrating an example of a relationship between initial value data that is output from the initial value generation module according to the first embodiment and the design data. In FIG. 10, a mask shape DM calculated as the initial value data 26 is represented a solid line. In addition, the lithography target DR is represented by a one-dot chain line.

As illustrated in FIG. 10, the mask shape DM has a portion that surrounds the lithography target DR and a portion formed at a position away from the lithography target DR (portion hatched in FIG. 10). Among these, the portion formed at the position away from the lithography target DR contributes to the formation of the resist shape corresponding to the lithography target DR, but is a portion that is not left as the resist shape itself. Such a portion is also called a sub-resolution assist feature (SRAF). As described above, the initial value generation module 22 can calculate the initial value data 26 of the mask shape including the SRAF by solving the linear problem of Equation (11) using the pseudo inverse lithography technology.

### 1.2 Operation

Next, an operation of the mask data generation device according to the first embodiment will be described.

### 1.2.1 Initial Value Generation Processing

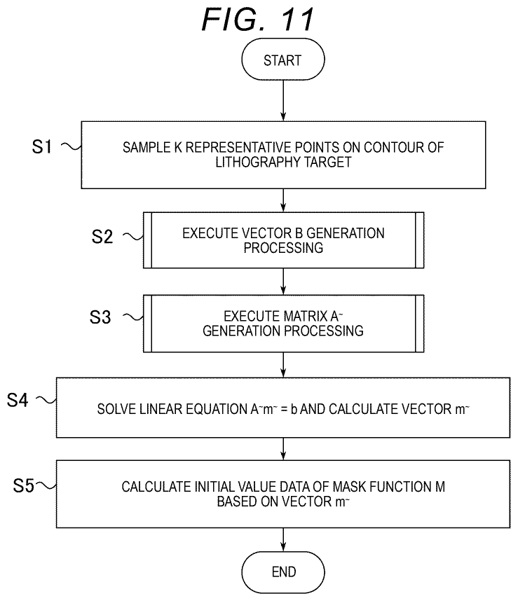

FIG. 11 is a flowchart illustrating an example of initial value generation processing in the initial value generation module according to the first embodiment.

When the design data 25 is received from the design module 21 (start), the vector generation unit 31 of the initial value generation module 22 samples K representative points (xₖ, yₖ) on the contour of the lithography target DR in the design data 25 (S₁).

The vector generation unit 31 executes vector generation processing based on the K representative points (xₖ, yₖ) sampled in the processing of S₁ (S₂). A vector b is generated by the vector generation processing.

The matrix generation unit 32 executes a matrix generation processing based on the Socs kernel 29 (S₃). A matrix A is generated by a matrix generation processing.

The linear solver 33 solves the linear equation Am=b based on the vector b generated in the processing of S2 and the matrix A generated in the processing of S3 (S4). Thereby, the linear solver 33 calculates the vector m.

The inverse Fourier transform unit 34 calculates the initial value data 26 of the mask function M based on the vector m calculated in the processing of S4 (S5). Specifically, the inverse Fourier transform calculates the initial value data 26 by executing the inverse Fourier transform on the vector m.

When the processing of S5 ends, the initial value generation processing ends (end).

### 1.2.2 Vector Generation Processing

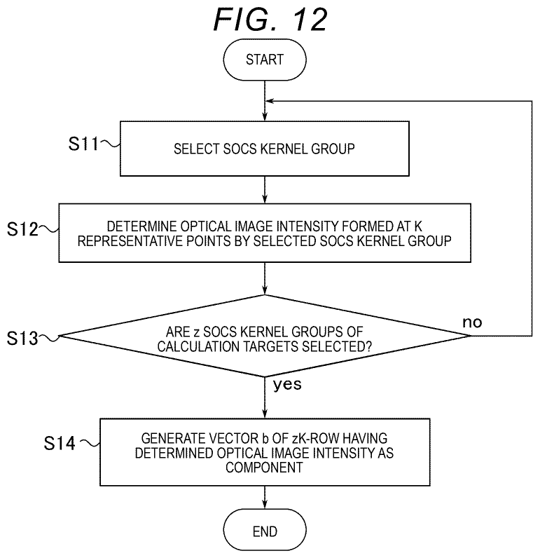

FIG. 12 is a flowchart illustrating an example of the vector generation processing in the initial value generation module according to the first embodiment. Processing of S11 to S14 illustrated in FIG. 12 corresponds to the processing of S2 in FIG. 11.

When the vector generation processing is started (start), the vector generation unit 31 selects one SOCs kernel group (S11). When selecting the socs kernel group, the vector generation unit 31 selects the SOCS kernel group, for example, in a descending order of the corresponding eigenvalues σ. That is, in the first processing of S11, the vector generation unit 31 selects the Socs kernel group corresponding to p=1.

The vector generation unit 31 determines the optical image intensity formed in common at the K representative points (xₖ, yₖ) by the SOCS kernel group selected in the processing of S11 (S12). For example, the vector generation unit 31 determines b₁ as an optical image intensity formed by the Socs kernel group corresponding to p=1.

The vector generation unit 31 determines whether z socs kernel groups, which are the calculation targets, are selected (S13). Here, when p=3 is considered as the calculation target, the integer z is 2.

When not all of the z SOCS kernel groups are selected as the calculation targets (S13; no), the vector generation unit 31 selects unselected SOCS kernel groups (S11). That is, in the second processing of S11, the vector generation unit 31 selects the Socs kernel group corresponding to p=2 and 3.

The vector generation unit 31 determines the optical image intensity formed in common at the K representative points (xₖ, yₖ) by the Socs kernel group selected in the processing of S11 (S12). For example, the vector generation unit 31 determines b₂ as the optical image intensity formed by the socs kernel group corresponding to p=2 and 3.

The vector generation unit 31 determines whether z Socs kernel groups, which are the calculation targets, are selected (S13).

When all the z SOCS kernel groups are selected as the calculation targets (S13; yes), the vector generation unit 31 generates the vector b of a zK-row having the optical image intensity determined in the processing of S12 as a component (S14).

When the processing of S14 is ended, the vector generation processing is ended (end).

### 1.2.3 Matrix Generation Processing

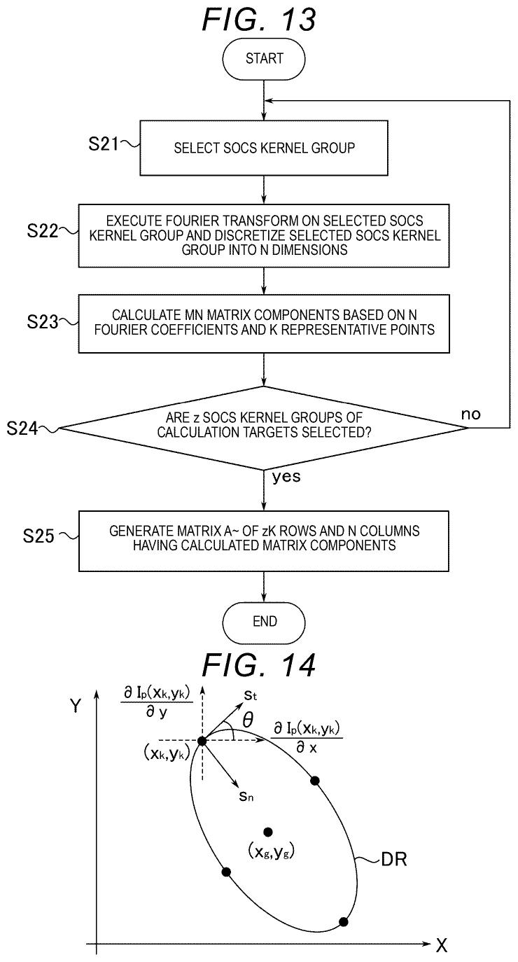

FIG. 13 is a flowchart illustrating an example of matrix generation processing in the initial value generation module according to the first embodiment. Processing of S21 to S24 illustrated in FIG. 13 corresponds to the processing of S3 in FIG. 11.

When the matrix generation processing is started (start), the matrix generation unit 32 selects one SOCs kernel group (S21). The selection method of the socs kernel group in the processing of S21 is the same as that in the processing of S11. That is, in the processing of the first S21, the matrix generation unit 32 selects the SOcs kernel group corresponding to p=1.

The matrix generation unit 32 performs the Fourier transform on the socs kernel group selected in the processing of S21 and discretizes the socs kernel group into N dimensions (S22). For example, the matrix generation unit 32 performs the Fourier transform on the eigenfunction S₁ of the Socs kernel group corresponding to p=1 to calculate N Fourier coefficients.

The matrix generation unit 32 calculates KN matrix components a^{~}_{1_11} to a^{~}_{1_KN} based on the N Fourier coefficients and K representative points (xₖ, yₖ) calculated in the processing of S22 (S23).

The matrix generation unit 32 determines whether the z SOCS kernel groups, which are calculation targets, are selected (S24). Here, when p=3 is considered as the calculation target, the integer z is 2.

When not all of the z SOCS kernel groups are selected as the calculation targets (S24; no), the matrix generation unit 32 selects the unselected SOCS kernel groups (S21). That is, in the second processing of S21, the matrix generation unit 32 selects the Socs kernel groups corresponding to p=2 and 3.

The matrix generation unit 32 performs the Fourier transform on the socs kernel group selected in the processing of S21 and discretizes the socs kernel group into N dimensions (S22). For example, the matrix generation unit 32 performs the Fourier transform on the eigenfunctions S₂ and S₃ of the SOCS kernel group corresponding to p=2 and 3 to calculate 2N Fourier coefficients.

The matrix generation unit 32 calculates the KN matrix components a^{~}_{2_11} to a^{~}_{2_KN} based on the 2N Fourier coefficients and K representative points (xₖ, yₖ) calculated in the processing of S22 (S23).

The matrix generation unit 32 determines whether the z SOCs kernel groups, which are calculation targets, are selected (S24).

When all of the z SOCS kernel groups, which are the calculation targets, are selected (S24; yes), the matrix generation unit 32 generates the matrix A of zK rows and N columns having the matrix components calculated in the processing of S23 (S25).

When the processing of S25 is ended, the matrix generation processing is ended (end).

### 1.3 Effects According to First Embodiment

According to the embodiment, the vector generation unit 31 samples K representative points (xₖ, yₖ) from the contour of the lithography target. The vector generation unit 31 and the matrix generation unit 32 select the eigenfunction S₁ of the first SOCS kernel provided in the TCC representing the projection optical system related to the mask shape corresponding to the lithography target. The vector generation unit 31 determines the optical image intensity b₁ at each of K representative points (xₖ, yₖ) corresponding to the convolution integral of the eigenfunction S₁ and the mask function M representing the mask shape, and generates the vector b corresponding to the optical image intensity b₁. The matrix generation unit 32 discretizes the convolution integral in N dimensions and generates the matrix A related to the eigenfunction S₁. The linear solver 33 solves the linear equation Am=b and calculates the vector m corresponding to the mask function M. The inverse Fourier transform unit 34 performs the inverse Fourier transform on the calculated vector m and calculates the mask function M. As a result, the mask function M can be calculated by solving the linear equation instead of directly solving Equation (1). Therefore, the calculation cost can be reduced, and high-speed calculation can be achieved.

The vector generation unit 31 determines the components of the vector b related to the eigenfunction S₁ to be the optical image intensity b₁. As a result, Equation (1) can be decomposed into conditions for each SOCS kernel as shown in Equation (2-1). Therefore, the conditions on the contour of the lithography target DR can be approximately linearized.

In addition, the matrix generation unit 32 generates the matrix A based on N Fourier coefficients S₁^{~} obtained by performing the Fourier transform on the eigenfunction S₁ as shown in Equation (8-1). As a result, it is possible to prevent the resolution in the real space from being limited by the dimension of the discretization. Therefore, the deterioration of the calculation accuracy can be reduced while avoiding an excessive increase in the calculation cost.

In addition, the linear solver 33 solves the linear equation using the LSMR method. As a result, even when the underdetermined problem and the coefficient matrix are under poor conditions as in Equation (11), the optimum solution can be obtained.

In addition, the vector generation unit 31 and the matrix generation unit 32 select the eigenfunctions S₂ and S₃ of the second and third SOCS kernels. The vector generation unit 31 further determines the optical image intensity b₂ at each of K representative points (xₖ, yₖ) corresponding to the sum of the convolution integral of the eigenfunction S₂ and the mask function M and the convolution integral of the eigenfunction S₃ and the mask function M, and generates the vector b further corresponding to the optical image intensity b₂. The matrix generation unit 32 discretizes the differentiation of the convolution integral in N dimensions and generates the matrix A further related to the differentiation of the eigenfunction S₁. Thereby, the SOCs kernel with the next-highest contribution degree to the optical image intensity after the first socs kernel can be further considered. As a result, the accuracy of the calculated mask function M can be improved.

The second and third Socs kernels are degenerated, and thus, the sum of the convolution integral is used as shown in Equation (2-2). As a result, even the Socs kernel that is degenerated can be linearized by being decomposed into conditions for each SOCS kernel.

### 2. SECOND EMBODIMENT

Next, a second embodiment will be described. The second embodiment is different from the first embodiment in that not only the condition related to the optical image intensity at the representative point but also the condition related to the differential value of the optical image intensity at the representative point and the condition related to the optical image intensity at the additional representative point in the mask are further considered. The following description mainly describes a configuration and an operation, which are different from those of the first embodiment. For a configuration and an operation equal to those of the first embodiment, the description will appropriately not be shown.

### 2.1 Pseudo Inverse Lithography Technology

A pseudo inverse lithography technology executed by an initial value generation module according to the second embodiment will be described.

FIG. 14 is a diagram illustrating an example of a condition considered by the initial value generation module according to the second embodiment. FIG. 14 illustrates one lithography target DR in the design data 25.

As illustrated in FIG. 14, in the second embodiment, the differential value of the optical image intensity at K representative points (xₖ, yₖ) sampled on the contour of the lithography target DR is considered. Two types of the differential values are determined in the tangential direction and the normal direction of the lithography target DR. The differential values sₜ and sₙ of the optical image intensity in the tangential direction and the normal direction at the representative points (xₖ, yₖ) on the contour the lithography target DR are represented by Equation (12) below.

$$\{ \begin{matrix}{s}_{t} = \frac{\partial {I}_{p} ( {x}_{k} , {y}_{k} )}{\partial x} cos ( θ ) + \frac{\partial {I}_{p} ( {x}_{k} , {y}_{k} )}{\partial y} sin ( θ ) \\ {s}_{n} = \frac{\partial {I}_{p} ( {x}_{k} , {y}_{k} )}{\partial x} sin ( θ ) - \frac{\partial {I}_{p} ( {x}_{k} , {y}_{k} )}{\partial y} cos ( θ )\end{matrix} \qquad ( 12 )$$

When substituting Equation (5) into Equation (12), Equation (13) below is obtained.

$$\{ \begin{matrix}{s}_{t 1} = {\int }_{- ∞}^{∞} {\int }_{- ∞}^{∞} \tilde{{S}_{1}} ( ξ , η ) \cdot \tilde{M} ( ξ , η ) \cdot i \{ ξcos ( θ ) + ηsin ( θ ) \} \cdot {e}^{i ξ {x}_{k} + i η {y}_{k}} d ξ d η \\ {s}_{n 1} = {\int }_{- ∞}^{∞} {\int }_{- ∞}^{∞} \tilde{{S}_{1}} ( ξ , η ) \cdot \tilde{M} ( ξ , η ) \cdot i \{ ξcos ( θ ) - ηsin ( θ ) \} \cdot {e}^{i ξ {x}_{k} + i η {y}_{k}} d ξ d η\end{matrix} \qquad ( 13 )$$

The same procedure as the procedure of obtaining the linear equation of Equation (11) through the procedure of discretization from Equation (5) is performed with respect to Equation (13). As a result, for the K representative points (xₖ, yₖ), K linear equations in the tangential direction and K linear equations in the normal direction can be obtained for each of the K SOCS kernel groups. That is, when z SOCS kernel groups are considered, 2zK linear equations related to the differential values can be obtained for K representative points (xₖ, yₖ). For example, the differential value sₜ is determined as a common value of 0 for K representative points (xₖ, yₖ). The differential value sₙ can be determined as any value other than 0, for example, as a positive value or a negative value. The differential value sₙ may determine a common value of 0 for K representative points (xₖ, yₖ), or may have different values. The signs of the differential values sₙ are determined to be the same signs for K representative points (xₖ, yₖ).

In addition, as illustrated in FIG. 14, in the second embodiment, the value (mask value) of the mask function M at the L₁ representative points (x_{g}, y_{g}) located at a center portion of the mask is further taken into consideration. The L₁ representative points (x_{g}, y_{g}) are disposed in L₁ different lithography targets DR, respectively. Here, L₁ is an integer of 1 or more. That is, the condition is given in which the mask values at the Ly representative points (x_{g}, y_{g}) inside the contour have a common constant by the convolution integral of the mask function M and the delta function δ as shown in Equation (14) below.

$$M ( x , y ) ⊗ δ ( x - {x}_{g} , y - {y}_{g} ) = {T}_{0} \qquad ( 14 )$$

Here, the constant T₀ is a transmittance of light through the mask.

Equation (14) can be expressed as Equation (15) below using the property of the delta function.

$${T}_{0} = {\int }_{- ∞}^{∞} {\int }_{- ∞}^{∞} \tilde{M} ( ξ , η ) {e}^{i ξ ( x - {x}_{g} ) + i η ( y - {y}_{g} )} d ξ d η \qquad ( 15 )$$

The same procedure as the procedure of obtaining the linear equation of Equation (11) from Equation (5) through the procedure of the discretization is performed with respect to Equation (15). As a result, L₁ linear equations can be obtained for L₁ representative points (x_{g}, y_{g}).

### 2.2 Functional Configuration

The vector generation unit 31 samples K representative points (xₖ, yₖ) on the contour of the lithography target DR shown in the design data 25 and L₁ representative points (x_{g}, y_{g}) inside the contour. The vector generation unit 31 determines zK conditions with respect to the optical image intensity and 2zK conditions with respect to the differentiation of the optical image intensity, respectively, for the K sampled representative points. The vector generation unit 31 determines L₁ conditions for the mask shape with respect to the L₁ sampled representative points. The vector generation unit 31 generates the vector b of the (3zK+L₁)th row in Equation (11) based on the determined conditions.

More specifically, in a case of z=2, the vector generation unit 31 determines the value b₁ corresponding to p=1 and the value b₂ corresponding to the set of p=2 and p=3 as values corresponding to the optical image intensity for K representative points. The vector generation unit 31 determines the values sₜ₁ and sₙ₁ corresponding to p=1 and values sₜ₂ and sₙ₂ corresponding to the set of p=2 and 3 as values corresponding to the differentiation of the optical image intensity for the K representative points. The vector generation unit 31 determines T₀ as a value corresponding to the mask shape for the L₁ representative points. The vector generation unit 31 generates the vector b in the (6K+L₁)th row in Equation (11) based on the determined values b₁, b₂, sₜ₁, sₙ₁, sₜ₂, sₙ₂, and T₀.

The matrix generation unit 32 performs the Fourier transform on the eigenfunction Sₚ of the SOCS kernel 29 and generates the matrix A of N rows and (3zK+L₁) columns in Equation (11). The matrix generation unit 32 transmits the generated matrix A to the linear solver 33.

The configurations of the linear solver 33 and the inverse Fourier transform unit 34 are the same as those in the first embodiment.

### 2.3 Operation

Next, an operation of the mask data generation device according to the second embodiment will be described.

### 2.3.1 Initial Value Generation Processing

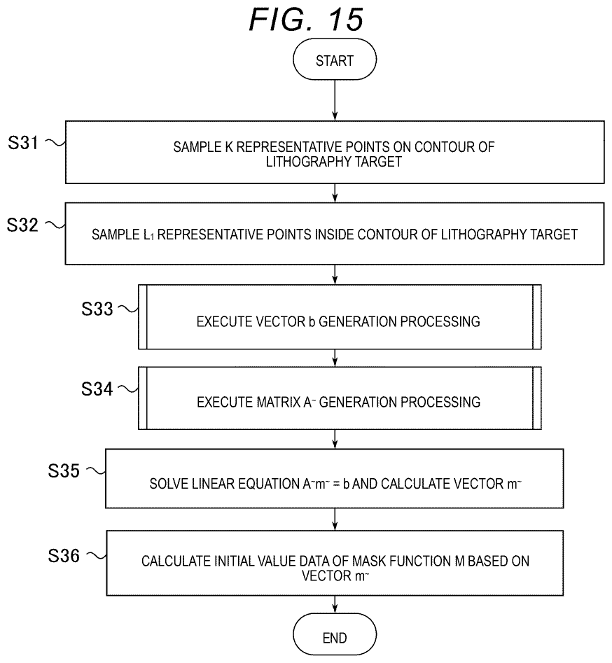

FIG. 15 is a flowchart illustrating an example of the initial value generation processing in the initial value generation module according to the second embodiment. FIG. 15 corresponds to FIG. 11 in the first embodiment.

When the design data 25 is received from the design module 21 (start), the vector generation unit 31 of the initial value generation module 22 samples the K representative points (xₖ, yₖ) on the contour of the lithography target DR in the design data 25 (S31).

The vector generation unit 31 samples the L₁ representative points (x_{g}, y_{g}) inside the contour of the lithography target DR in the design data 25 (S32).

The vector generation unit 31 executes the vector generation processing based on the (K+L₁) representative points sampled in the processing of S31 and S32 (S33). A vector b is generated by the vector generation processing.

The matrix generation unit 32 executes the matrix generation processing based on the socs kernel 29 (S34). A matrix A is generated by a matrix generation processing.

The linear solver 33 solves the linear equation Am=b based on the vector b generated in the processing of S33 and the matrix A generated in the processing of S34 (S35). Thereby, the linear solver 33 calculates the vector m.

The inverse Fourier transform unit 34 calculates the initial value data 26 of the mask function M based on the vector m calculated in the processing of S35 (S36). Specifically, the inverse Fourier transform unit 34 calculates the initial value data 26 by executing the inverse Fourier transform on the vector m.

When the processing of S36 is ended, the initial value generation processing is ended (end).

### 2.3.2 Vector Generation Processing

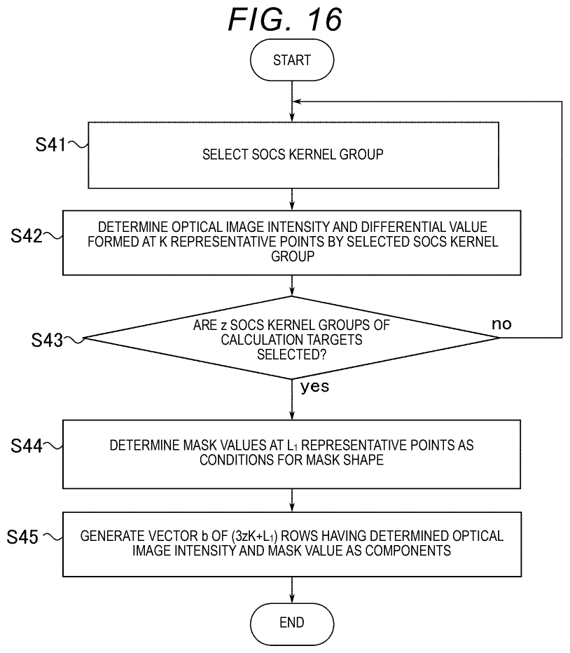

FIG. 16 is a flowchart illustrating an example of the vector generation processing in the initial value generation module according to the second embodiment. Processing of S41 to S45 illustrated in FIG. 16 corresponds to the processing of S33 in FIG. 15. FIG. 16 corresponds to FIG. 12 in the first embodiment.

When the vector generation processing is started (start), the vector generation unit 31 selects one SOCS kernel group (S41). When selecting the Socs kernel group, the vector generation unit 31 selects the Socs kernel group, for example, in a descending order of the corresponding eigenvalues σ. That is, in the first processing of S11, the vector generation unit 31 selects the socs kernel group corresponding to p=1.

The vector generation unit 31 determines the optical image intensity and the differential value, which are commonly formed at the K representative points (xₖ, yₖ) by the SOCS kernel group selected in the processing of S41 (S42). For example, the vector generation unit 31 determines b₁ as the optical image intensity formed by the SOCS kernel group corresponding to p=1, and determines sₜ₁ and sₙ₁ as the differential values in the tangential direction and the normal direction, respectively.

The vector generation unit 31 determines whether the z SOCS kernel groups of the calculation targets are selected (S43). Here, when p=3 is considered as the calculation target, the integer z is 2.

When not all of the z SOCS kernel groups of the calculation targets are selected (S43; no), the vector generation unit 31 selects the unselected SOCS kernel groups (S41). That is, in the second processing of S41, the vector generation unit 31 selects the SOCS kernel groups corresponding to p=2 and 3.

The vector generation unit 31 determines the optical image intensity and the differential value, which are commonly formed at the K representative points (xₖ, yₖ) by the socs kernel group selected in the processing of S41 (S42). For example, the vector generation unit 31 determines b₂ as the optical image intensity formed by the Socs kernel groups corresponding to p=2 and 3, and determines sₜ₂ and sₙ₂ as the differential values in the tangential direction and the normal direction, respectively.

The vector generation unit 31 determines whether the z Socs kernel groups of the calculation targets are selected (S43).

When all the z SOCS kernel groups are selected as the calculation targets (S43; yes), the vector generation unit 31 determines the mask values at L₁ representative points (x_{g}, y_{g}) as conditions for the mask shape (S44).

The vector generation unit 31 generates the vector b of (3zK+L₁) rows having the optical image intensity and the differential value determined in the processing of S42 and the mask value determined in the processing of S44 as components (S45).

When the processing of S45 is ended, the vector generation processing is ended (end).

### 2.3.3 Matrix Generation Processing

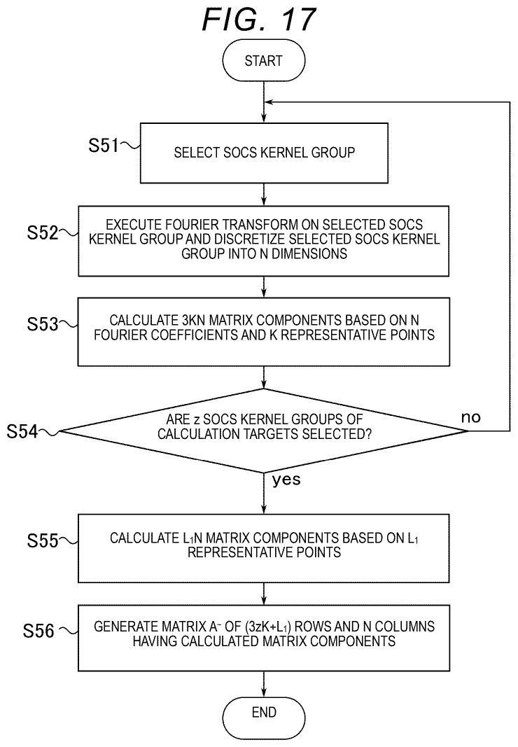

FIG. 17 is a flowchart illustrating an example of the matrix generation processing in the initial value generation module according to the second embodiment. The processing of S51 to S56 illustrated in FIG. 17 corresponds to the processing of S34 in FIG. 15. FIG. 17 corresponds to FIG. 13 in the second embodiment.

When the matrix generation processing is started (start), the matrix generation unit 32 selects one SoCs kernel group (S51). The selection method of the Socs kernel group in the processing of S51 is the same as the processing of S41. That is, in the first processing of the S51, the matrix generation unit 32 selects the Socs kernel group corresponding to p=1.

The matrix generation unit 32 performs the Fourier transform on the SOCS kernel group selected in the processing of S51 and discretizes the Socs kernel group into N dimensions (S52). For example, the matrix generation unit 32 performs the Fourier transform on the eigenfunction S₁ of the Socs kernel group corresponding to p=1 to calculate N Fourier coefficients.

The matrix generation unit 32 calculates 3KN matrix components based on the N Fourier coefficients and K representative points (xₖ, yₖ) calculated in the processing of S52 (S53). Among the 3KN, KN's are matrix components a^{~}_{1_1} to a^{~}_{1_KN} related to the optical image intensity, and the remaining 2KN are matrix components related to the differential value of the optical image intensity.

The matrix generation unit 32 determines whether the z SOCs kernel groups of the calculation targets are selected (S54). Here, when p=3 is considered as the calculation target, the integer z is 2.

When not all of the z SOCS kernel groups of the calculation targets are selected (S54; no), the matrix generation unit 32 selects the unselected SOCS kernel groups (S51). That is, in the second processing of S51, the matrix generation unit 32 selects the Socs kernel groups corresponding to p=2 and 3.

The matrix generation unit 32 performs the Fourier transform on the Socs kernel group selected in the processing of S51 and discretizes the Socs kernel group into N dimensions (S52). For example, the matrix generation unit 32 performs the Fourier transform on the eigenfunctions S₂ and S₃ of the SOCS kernel group corresponding to p=2 and 3 to calculate 2N Fourier coefficients.

The matrix generation unit 32 calculates 3KN matrix components based on the 2N Fourier coefficients and the K representative points (xₖ, yₖ) calculated in the processing of S52 (S53). Among the 3KN, KN's are matrix components a^{~}_{2_11} to a^{~}_{2_KN} related to the optical image intensity, and the remaining 2KN are matrix components related to the differential value of the optical image intensity.

The matrix generation unit 32 determines whether the z SOcs kernel groups of the calculation targets are selected (S54).

When all of the z SOCS kernel groups of the calculation targets are selected (S54; yes), the matrix generation unit 32 calculates LIN matrix components based on L₁ representative points (x_{g}, y_{g}) (S55).

The matrix generation unit 32 generates the matrix A of (3zK+L₁) rows and N columns having 3zKN matrix components calculated in the processing of S53 and LIN matrix components calculated in the processing of S55 (S56).

When the processing of S56 is ended, the matrix generation processing is ended (end).

### 2.4 Effects According to Second Embodiment

According to the second embodiment, the initial value generation module 22 further considers the differential value of the optical image intensity for K representative points (xₖ, yₖ). The differential value includes the differential value St in the tangential direction of the contour of the lithography target DR and the differential value sₙ in the normal direction. As a result, the condition number of the linear equation can be increased, and thus the mask shape can be calculated more accurately.

In addition, the initial value generation module 22 further takes into consideration that the mask values at the L₁ representative points (x_{g}, y_{g}) located inside the contour of the lithography target DR are set to the constant T₀. As a result, the condition number of the linear equation can be increased, and thus the mask shape can be calculated more accurately.

### 3. MODIFICATION EXAMPLES AND THE LIKE

Various modifications may be applied to the first embodiment and the second embodiment described above.

Although the case of obtaining the mask function M by solving the linear equation once is described in the second embodiment, the present disclosure is not limited thereto. For example, the initial value generation module 22 may be configured to improve the accuracy of the mask function M by solving the linear equation multiple times by iteration.

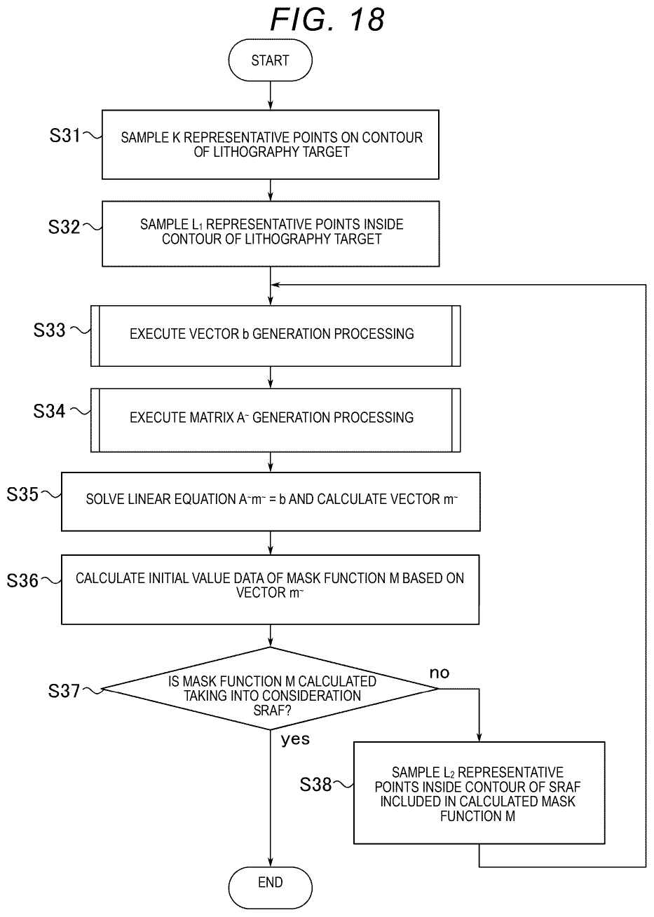

FIG. 18 is a flowchart illustrating an example of the initial value generation processing in the initial value generation module according to the modification example. FIG. 18 corresponds to FIG. 15 in the second embodiment.

As illustrated in FIG. 18, the first processing of S31 to S36 is the same as the processing of S31 to S36 in FIG. 15.

After the processing of S36, the initial value generation module 22 determines whether to further execute the calculation of the mask function M, taking into consideration the SRAF provided in the mask function M calculated in the processing of S36 (S37).

When the calculation of the mask function M is not executed in consideration of the SRAF (S37; no), the vector generation unit 31 further Samples the L₂ representative points in the contour of the SRAF provided in the mask function M calculated in the processing of S36 (S38). Here, L₂ is an integer of 1 or more. As a result, the number of representative points sampled inside the mask shape is (L₁+L₂).

After the processing of S38, the initial value generation module 22 generates the vector b and the matrix A, calculates the vector m, and executes the calculation of the mask function M based on K representative points sampled on the contour of the lithography target DR and (L₁+L₂) representative points sampled inside the mask shape (S33 to S36). In the processing of S33 to S36, the initial value generation module 22 processes the L₂ representative points sampled in the processing of S38 to be equivalent to the L₁ representative points sampled in the processing of S32. That is, the number of rows of the vector b and the matrix A related to the (L₁+L₂) representative points sampled inside the mask shape is (L₁+L₂). The mask value determined related to the L₂ representative points in the generation processing of the vector b may be equal to the mask value determined related to the L₁ representative points, or may be different from the mask value determined related to the L₂ representative points.

When the calculation of the mask function M is executed in consideration of the SRAF (S37; yes), the initial value data generation processing is ended (end).

By operating as described above, the mask shape can be calculated by taking into consideration the presence of the SRAF that does not appear in the design data 25. As a result, the accuracy of the mask shape can be further improved.

In addition, in the second embodiment described above, a case where the differential value of the optical image intensity is determined for all the K representative points (xₖ, yₖ) is described, but the present disclosure is not limited thereto. For example, the differential value of the optical image intensity may be determined for at least one of the K representative points (xₖ, yₖ). More specifically, for example, the differential value of the optical image intensity may be determined, one for each side of the rectangular lithography target DR, and may not be determined for the vertex.

In addition, in the first embodiment and the second embodiment described above, a case where the program for executing the initial generation processing is executed by the initial value generation module 22 is described, but the present disclosure is not limited thereto. For example, the program for executing the initial generation processing may be executed by a calculation resource on a cloud.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A mask shape calculation method comprising:
sampling K representative points from a contour of a lithography target, wherein K is an integer equal to or greater than 1;
selecting a first kernel provided in a first function representing a projection optical system related to a mask shape corresponding to the lithography target;
determining a first optical image intensity at each of the K representative points corresponding to a first convolution integral of the first kernel and a second function representing the mask shape;
discretizing the first convolution integral into N dimensions to generate (i) a first matrix of K rows and N columns related to the first kernel; and (ii) a first vector of K rows related to the first optical image intensity; and
solving a linear equation Am=b using a matrix A including the first matrix, a vector b including the first vector, and a vector m corresponding to the second function, and calculating the second function.

2. The mask shape calculation method according to claim 1, wherein K components of the first vector are equal to each other.

3. The mask shape calculation method according to claim 1, wherein the generating includes generating the first matrix based on N Fourier coefficients obtained by performing a Fourier transform on the first kernel.

4. The mask shape calculation method according to claim 1, wherein the calculating includes calculating the second function by performing an inverse Fourier transform on the vector m obtained as a solution of the linear equation.

5. The mask shape calculation method according to claim 1, wherein the calculating includes solving the linear equation by a least square minimum-residual method (LSMR method).

6. The mask shape calculation method according to claim 1, further comprising:
selecting a second kernel and a third kernel provided in the first function;
determining a second optical image intensity at each of the K representative points corresponding to a sum of a second convolution integral of the second kernel and the second function and a third convolution integral of the third kernel and the second function; and
further discretizing a sum of the second convolution integral and the third convolution integral into N-dimensions, to generate (i) a second matrix of K rows and N columns related to the second kernel and the third kernel; and (ii) a second vector of K rows related to the second optical image intensity, wherein
the calculating includes solving the linear equation Am=b using a matrix A of 2K rows and N columns including the first matrix and the second matrix, a vector b of 2K rows including the first vector and the second vector, and the vector m corresponding to the second function, and calculating the second function.

7. The mask shape calculation method according to claim 6, wherein an eigenvalue of the first kernel is greater than an eigenvalue of the second kernel and an eigenvalue of the third kernel.

8. The mask shape calculation method according to claim 6, wherein each of the second kernel and the third kernel is degenerated.

9. The mask shape calculation method according to claim 1, further comprising:
determining a differential value of the first optical image intensity at at least one point of the K representative points corresponding to a differentiation of the first convolution integral; and
discretizing the differentiation of the first convolution integral into N dimensions to generate (i) a third matrix related to the first kernel; and (ii) a third vector related to the differentiation of the first optical image intensity, wherein
the calculating includes solving the linear equation Am=b using a matrix A including the first matrix and the third matrix, a vector b including the first vector and the third vector, and the vector m corresponding to the second function, and calculating the second function.

10. The mask shape calculation method according to claim 9, wherein the differential value includes at least one of a first differential value in a tangential direction and a second differential value in a normal direction in the contour of the lithography target.

11. The mask shape calculation method according to claim 10, wherein the first differential values determined at at least one point of the K representative points are all 0.

12. The mask shape calculation method according to claim 10, wherein the second differential values determined at at least one point of the K representative points have signs that are equal to each other.

13. The mask shape calculation method according to claim 1, further comprising:
sampling L₁ representative points from an inside of the contour of the lithography target (L₁ is an integer of 1 or more);
determining a first mask value at each of the L₁ representative points corresponding to a fourth convolution integral of a first delta function related to the L₁ representative points and the second function; and
discretizing the fourth convolution integral into N dimensions to generate (i) a fourth matrix of L₁ rows and N columns related to the first delta function; and (ii) a fourth vector of L₁ rows related to the first mask value, wherein
the calculating includes solving the linear equation Am=b using a matrix A including the first matrix and the fourth matrix, a vector b including the first vector and the fourth vector, and the vector m corresponding to the second function, and calculating the second function.

14. The mask shape calculation method according to claim 13, further comprising:
sampling L₂ representative points from an inside of a contour not associated with the lithography target among the calculated second functions;
determining a second mask value at each of the L₂ representative points corresponding to a fifth convolution integral of a second delta function related to the L₂ representative points and the second function; and
discretizing the fifth convolution integral into N dimensions to generate (i) a fifth matrix of L₂ rows and N columns related to the second delta function; and (ii) a fifth vector of L₂ rows related to the second mask value (L₂ is an integer of 1 or more), wherein
the calculating includes solving the linear equation Am=b using the matrix A including the first matrix, the fourth matrix, and the fifth matrix, a vector b including the first vector, the fourth vector, and the fifth vector, and the vector m corresponding to the second function, and calculating the second function.

15. The mask shape calculation method according to claim 14, wherein the first mask values at each of the L₁ representative points are equal to each other.

16. The mask shape calculation method according to claim 15, wherein the second mask values at each of the L₂ representative points are equal to each other.

17. The mask shape calculation method according to claim 16, wherein the first mask value and the second mask value are equal to each other.

18. A program for causing a computer to execute:
sampling K representative points from a contour of a lithography target, wherein K is an integer equal to or greater than 1;
selecting a first kernel provided in a first function representing a projection optical system related to a mask shape corresponding to the lithography target;
determining a first optical image intensity at each of the K representative points corresponding to a first convolution integral of the first kernel and a second function representing the mask shape;
discretizing the first convolution integral into N dimensions to generate (i) a first matrix of K rows and N columns related to the first kernel; and (ii) a first vector of K rows related to the first optical image intensity; and
solving a linear equation Am=b using a matrix A including the first matrix, a vector b including the first vector, and a vector m corresponding to the second function, and calculating the second function.

19. A storage medium on which a program is stored, the program for causing a computer to execute:
sampling K representative points from a contour of a lithography target, wherein K is an integer equal to or greater than 1;
selecting a first kernel provided in a first function representing a projection optical system related to a mask shape corresponding to the lithography target;
determining a first optical image intensity at each of the K representative points corresponding to a first convolution integral of the first kernel and a second function representing the mask shape;
discretizing the first convolution integral into N dimensions to generate (i) a first matrix of K rows and N columns related to the first kernel; and (ii) a first vector of K rows related to the first optical image intensity; and
solving a linear equation Am=b using a matrix A including the first matrix, a vector b including the first vector, and a vector m corresponding to the second function, and calculating the second function.
